(19) United States
(12) Patent Application Publication
(10) Pub. No.: US 2012/0299036 A1
(43) Pub. Date: Nov. 29, 2012

(54) THERMALLY ENHANCED LIGHT EMITTING DEVICE PACKAGE

(75) Inventors: AN HONG LIU, TAINAN COUNTY (TW); RUENN BO TSAI, TAINAN COUNTY (TW); DAVID WEI WANG, TAINAN COUNTY (TW)

(73) Assignee: CHIPMOS TECHNOLOGIES INC., HSINCHU (TW)

(21) Appl. No.: 13/116,318

(22) Filed: May 26, 2011

(51) Int. Cl. H01L 33/64; H01L 33/60; H01L 33/58; H01L 33/62; H01L 33/52

(52) U.S. Cl. 257/98; 257/99; 257/E33.066; 257/E33.075; 257/E33.059; 257/E33.072; 257/E33.073

(57) ABSTRACT

A thermally enhanced light emitting device package includes a substrate, a chip attached to the substrate, an encapsulant overlaid on the chip, and a plurality of non-electrically conductive carbon nanocapsules mixed in the encapsulant to facilitate heat dissipation from the chip.

### BACKGROUND OF THE INVENTION

1. Field of the Invention

The present invention relates to a light emitting device package, and relates more particularly to a thermally enhanced light emitting device package.

2. Description of the Related Art

Due to their low power consumption and high illumination efficiency, LEDs are increasingly adopted in many electronic devices such as mobile devices, advertising light boxes, screens, signal lights, automotive vehicle signal lights, etc. As is well known, LEDs generate a significant amount of heat when they emit light, and heat sinks are necessary to dissipate the generated heat.

An LED package is primarily constituted by a heat sink, an LED disposed on the heat sink, and an encapsulant covering the LED. Light from the LED is emitted externally through the encapsulant. Because the encapsulant is usually made of polymer having poor thermal conductivity, most of the generated heat is dissipated through the heat sink.

To attain high illumination levels, high power LEDs are necessary. High power LEDs generate more heat that cannot be sufficiently dissipated by heat sinks. Therefore, complex heat dissipation designs are required, increasing the volume, weight, and cost of LED packages.

### SUMMARY OF THE INVENTION

One embodiment of the present invention provides a thermally enhanced light emitting device package, which comprises a leadframe, a chip, a plurality of metal wires, an encapsulant, and a plurality of non-electrically conductive carbon nanocapsules. The chip is attached to the leadframe. The metal wires electrically connect the chip and the leadframe. The plurality of non-electrically conductive carbon nanocapsules are mixed in the encapsulant where the encapsulant encapsulates the leadframe, the chip, and the metal wires.

Another embodiment of the present invention provides a thermally enhanced light emitting device package, which comprises a substrate, a chip, an encapsulant, and a plurality of non-electrically conductive carbon nanocapsules where a plurality of bumps are disposed on the bond pads of the chip. The chip is a flip chip disposed on the substrate. The plurality of non-electrically conductive carbon nanocapsules are mixed in the encapsulant where the encapsulant encapsulates at least part of the substrate, the chip, and the bumps.

Another embodiment of the present invention provides a thermally is enhanced light emitting device package, which comprises a substrate, a chip, an encapsulant, a plurality of metal wires electrically connecting the chip and the substrate, a plurality of metal wires, a lens, and another plurality of non-electrically conductive carbon nanocapsules mixed in the lens where the encapsulant encapsulates at least part of the substrate, the chip, and the metal wires.

To better understand the above-described objectives, characteristics and advantages of the present invention, embodiments, with reference to the drawings, are provided for detailed explanations.

### BRIEF DESCRIPTION OF THE DRAWINGS

The invention will be described according to the appended drawings in which:

FIG. 1 is a cross-sectional view illustrating a thermally enhanced light emitting device package according to a first embodiment of the present invention;

FIG. 2 is a cross-sectional view illustrating a thermally enhanced light emitting device package according to a second embodiment of the present invention;

FIG. 3 is a cross-sectional view illustrating a thermally enhanced light emitting device package according to a third embodiment of the present invention;

FIG. 4 is a cross-sectional view illustrating a thermally enhanced light emitting device package according to a fourth embodiment of the present invention;

FIG. 5 is a cross-sectional view illustrating a thermally enhanced light emitting device package according to a fifth embodiment of the present invention;

FIG. 6 is a cross-sectional view illustrating a thermally enhanced light emitting device package according to a sixth embodiment of the present invention;

FIG. 7 is a cross-sectional view illustrating a thermally enhanced light emitting device package according to a seventh embodiment of the present invention; and

FIG. 8 is a cross-sectional view illustrating a thermally enhanced light emitting device package according to an eighth embodiment of the present invention.

### DETAILED DESCRIPTION OF THE INVENTION

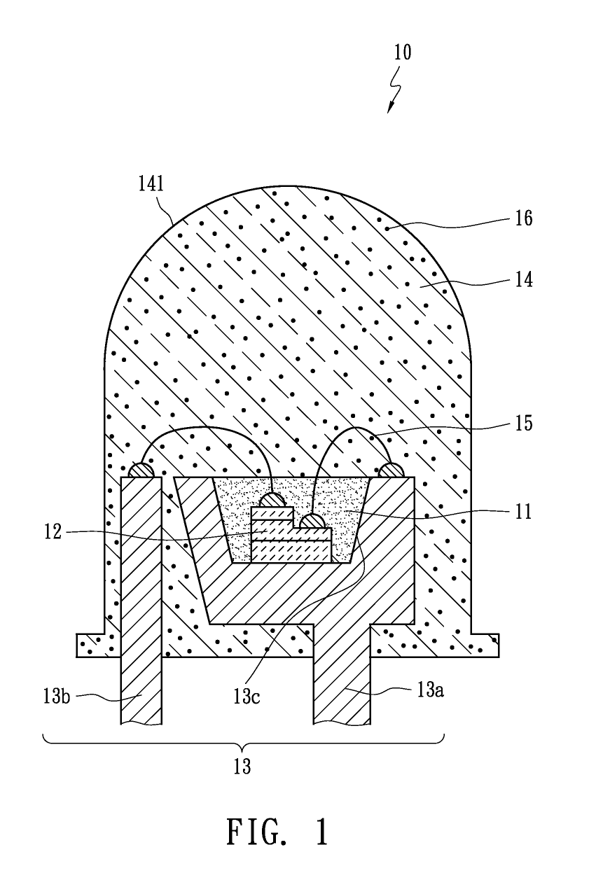

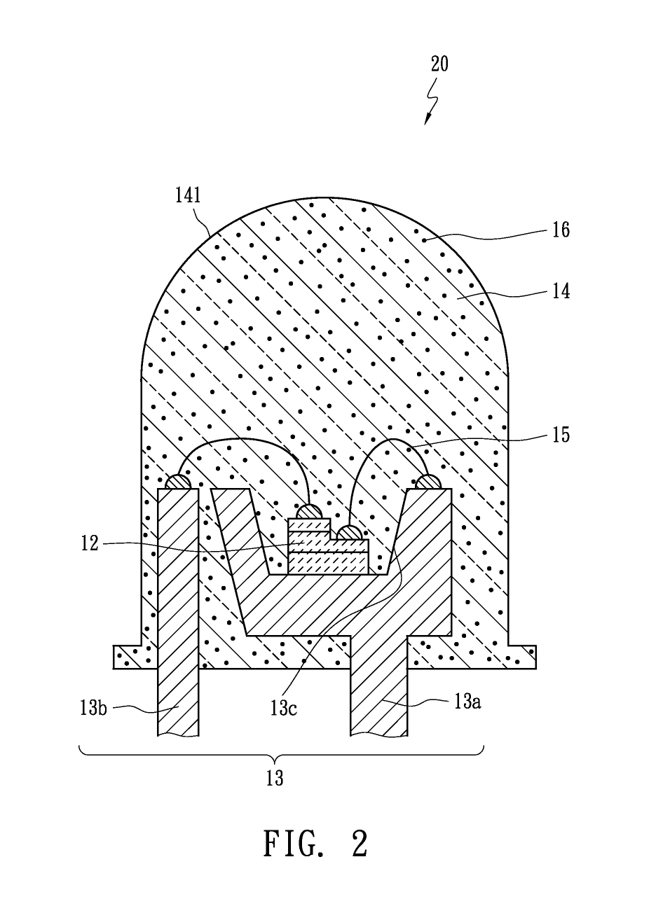

FIG. 1 is a cross-sectional view illustrating a thermally enhanced light emitting device package 10 according to a first embodiment of the present invention. FIG. 2 is a cross-sectional view illustrating a thermally enhanced light emitting device package 20 according to a second embodiment of the present invention. Referring to FIGS. 1 and 2, the thermally enhanced light emitting device package 10 or 20 comprises a leadframe 13, a chip 12 attached to the leadframe 13, a plurality of metal wires 15 electrically connecting the chip 12 and the leadframe 13, an encapsulant 14 mixed with a plurality of non-electrically conductive carbon nanocapsules 16 and encapsulating the chip 12, the leadframe 13, and the metal wires 15.

As shown in FIG. 1, the thermally enhanced light emitting device package 10 may further comprise a fluorescent adhesive 11 overlaid on the chip 12, converting a portion of light from the chip 12 into complementary color light combined with another portion of light from the chip 12 to simulate white light.

In one embodiment, the fluorescent adhesive 11 can be mixed with a plurality of non-electrically conductive carbon nanocapsules 16.

As shown in FIGS. 1 and 2, the leadframe 13 may include a cathode 13a and an anode 13b. As is well known, the chip 12 is comprised of is semiconducting material doped with impurities to create a p-n junction. Current flows from the anode 13b or p-side to the cathode 13a or n-side, and when an electron collides with a hole, energy is released in the form of a photon, i.e., light. Therefore, when electrons continue to collide with holes, light will emit continuously.

Referring to FIGS. 1 and 2 again, the leadframe 13 may further comprise a downset 13c, in which the chip 12 is disposed. The fluorescent adhesive 11 is disposed in the downset 13c to encapsulate the chip.

The encapsulant 14 can be formed to encapsulate the end portion of the cathode 13a, the end portion of the anode 13b, the downset 13c, and the chip 12 in the embodiment of FIG. 1, and is formed to further encapsulate the fluorescent adhesive 11 in the embodiment of FIG. 2. The encapsulant 14 can further be formed to include a lens part 141 for focusing emitted light to enhance light intensity and to control light emitting directions. The encapsulant 14 is comprised of dielectric resin material. In one embodiment, the encapsulant 14 can be comprised of thermosetting polymer such as silicone, epoxy resin, urethane, acrylics, or the like. In an alternative embodiment, the encapsulant 14 can be comprised of a thermoplastic material such as polyethylene, polypropylene, polycarbonate, polyethylene terephthalate, polyacrylate, acrylonitrile-styrene-butadiene copolymer, or the like.

As illustrated in FIGS. 1 and 2, the thermally enhanced light emitting device package 10 or 20 includes a plurality of non-electrically conductive carbon nanocapsules 16 distributed in the encapsulant 14 such that a heat dissipating path is formed inside the encapsulant 14. The plurality of non-electrically conductive carbon nanocapsules 16 can facilitate the dissipation of heat from the chip 12. Specifically, the plurality of non-electrically conductive carbon nanocapsules 16 can absorb the heat from the chip 12 and dissipate it in the form of infrared radiation.

In one embodiment, the surfaces of the carbon nanocapsules 16 can be functionalized to achieve good interfacial adhesion between the carbon nanocapsules 16 and the encapsulant 14.

The carbon nanocapsules 16 can effectively dissipate heat from the chip 12; thus a low loading of carbon nanocapsules 16 is sufficient for heat dissipation purpose. In one embodiment, 10% or less, preferably 1%, by weight of carbon nanocapsules 16 is blended into the encapsulant 14 and such a low loading will not compromise the light transmission through the encapsulant 14.

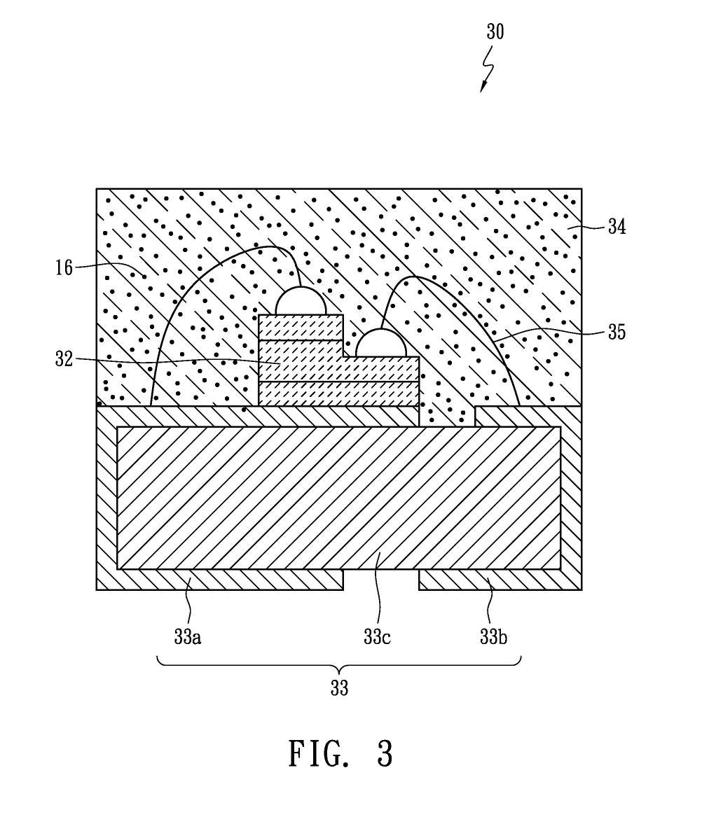

FIG. 3 is a cross-sectional view illustrating a thermally enhanced light emitting device package 30 according to a third embodiment of the present invention. Referring to FIG. 3, the thermally enhanced light emitting device package 30 comprises a substrate 33, a chip 32 attached to the substrate 33, a plurality of metal wires 35 electrically connecting the chip 32 and the substrate 33, an encapsulant 34 mixed with a plurality of non-electrically conductive carbon nanocapsules 16 and encapsulating the chip 32, the substrate 33 and a plurality of metal wires 35.

As shown in FIG. 3, the substrate 33 may include a cathode 33a, an anode 33b, and a support portion 33c. Each of the cathode 33a and the anode 33b is formed on the support portion 33c, extending along and from one surface of the support portion 33c, around a corresponding sidewall, to and along an opposite surface. In one embodiment, the chip 32 is disposed on the cathode 33a. The substrate 33 may be a printed circuit board such as FR-4, FR-5, BT, or the like, a metal-core printed circuit board, a ceramic substrate, a flex film, or the like.

The encapsulant 34 mixed with the plurality of non-electrically conductive carbon nanocapsules 16 is disposed on top of the substrate 33 and encapsulates the chip 32 and the wires 35 for dissipating heat generated by the chip 32. Similar to the above embodiment, 10% or less, preferably 1%, by weight of carbon nanocapsules 16 is sufficient for heat dissipation is purpose. The encapsulant 34 is comprised of dielectric resin material. In one embodiment, the encapsulant 34 can be comprised of thermosetting polymer such as silicone, epoxy resin, urethane, acrylics, or the like. In another embodiment, the encapsulant 34 can be comprised of a thermoplastic material such as polyethylene, polypropylene, polycarbonate, polyethylene terephthalate, polyacrylate, acrylonitrile-styrene-butadiene copolymer, or the like.

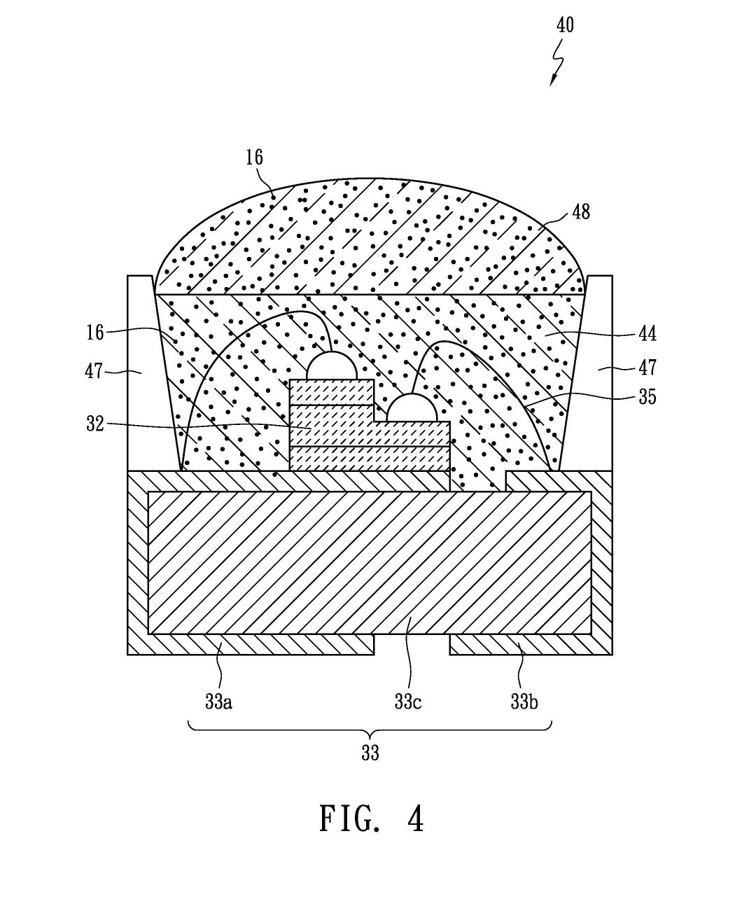

FIG. 4 is a sectional view showing a thermally enhanced light emitting device package 40 according to a fourth embodiment of the present invention. Referring to FIG. 4, the thermally enhanced light emitting device package 40 comprises a substrate 33, a chip 32 attached to the substrate 33, a plurality of metal wires 35 electrically connecting the chip 32 and the substrate 33, an encapsulant 44 encapsulating the chip 32 and the top surface of the substrate 33, and a plurality of non-electrically conductive carbon nanocapsules 16 mixed in the encapsulant 44.

The substrate 33 is analogous to that of the embodiment of FIG. 3, including an anode 33b and a cathode 33a, to which the chip 32 is attached.

As shown in FIG. 4, the thermally enhanced light emitting device package 40 comprises a reflector 47 formed on the substrate 33 for reflecting the light emitted from the chip 32 in the desired direction. The reflector 47 can be an additional component attached to the peripheries of the substrate 33 before encapsulation or part of the substrate 33 to be filled with encapsulant 44.

The encapsulant 44 can encapsulate the chip 32 and the wires 35. The encapsulant 44 is comprised of dielectric resin material. In one embodiment, the encapsulant 44 can be comprised of thermosetting polymer such as silicone, epoxy resin, urethane, acrylics, or the like. In another embodiment, the encapsulant 44 can alternatively be comprised of a thermoplastic material such as polyethylene, polypropylene, polycarbonate, polyethylene terephthalate, polyacrylate, acrylonitrile-styrene-butadiene is copolymer, or the like. The encapsulant 44 can be mixed with 10% or less, preferably 1%, by weight of carbon nanocapsules 16 for dissipating heat from the chip 32.

In FIG. 4, the thermally enhanced light emitting device package 40 may further comprise a lens 48 disposed on the encapsulant 44 for directing light in the desired direction. The lens 48 can include 10% or less by weight of carbon nanocapsules 16 so that a heat dissipating path can be formed therein. The lens 48 can be comprised of thermosetting polymer such as silicone, epoxy resin, urethane, acrylics, or the like, or can alternatively be comprised of a thermoplastic material such as polyethylene, polypropylene, polycarbonate, polyethylene terephthalate, polyacrylate, acrylonitrile-styrene-butadiene copolymer, or the like.

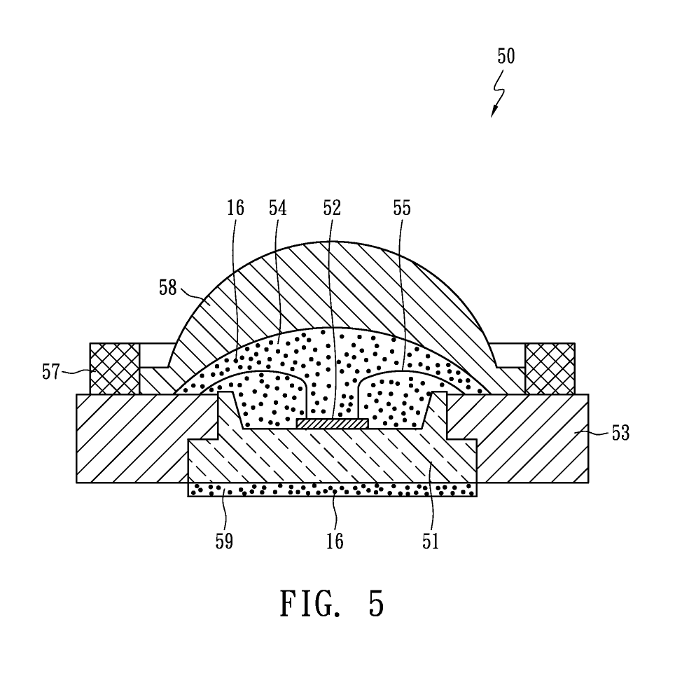

FIG. 5 is a cross-sectional view illustrating a thermally enhanced light emitting device package 50 according to a fifth embodiment of the present invention. Referring to FIG. 5, the thermally enhanced light emitting device package 50 comprises a substrate 53, a chip 52, a plurality of metal wires 55 electrically connecting the substrate 53 and the chip 52, an encapsulant 54 encapsulating the chip 52, and a plurality of non-electrically conductive carbon nanocapsules 16.

As shown in FIG. 5, the substrate 53 can be a printed circuit board having an opening. A thermal dissipation element 51 may be further provided in the thermally enhanced light emitting device package 50, inserted in the opening of the substrate 53, with the chip 52 disposed on the thermal dissipation element 51. The thermal dissipation element 51 can be made of, for example, metal.

The encapsulant 54 encapsulates the chip 52 and the metal wires 55. A plurality of non-electrically conductive carbon nanocapsules 16 are mixed in the encapsulant 54 so that heat generated by the chip 52 can effectively dissipate through the encapsulant 54 by thermal radiation. In one embodiment, 10% or less, preferably 1%, by weight of carbon nanocapsules is 16 are mixed in the encapsulant 54.

As shown in FIG. 5, an electrically insulating material 59 is further provided to cover the exposed surface of the thermal dissipation element 51 for electrical insulation. A plurality of non-electrically conductive carbon nanocapsules 16 may be contained in the electrically insulating material 59 so as to allow the heat generated by the chip 52 to dissipate effectively through the electrically insulating material 59. The electrically insulating material 59 can be comprised of a thermosetting polymer such as silicone, epoxy resin, urethane, or acrylics, or of a thermoplastic material such as polyethylene, polypropylene, polycarbonate, polyethylene terephthalate, polyacrylate, acrylonitrile-styrene-butadiene copolymer. In one embodiment, 10% or less, preferably 1%, by weight of carbon nanocapsules 16 are mixed in the electrically insulating material 59 based on the total amount of the mixture of the electrically insulating material 59 and the carbon nanocapsules 16.

Referring to FIG. 5 again, the thermally enhanced light emitting device package 50 may further comprise a lens 58 disposed on the encapsulant 54 for directing light in the desired direction. The lens 58 can be comprised of thermosetting polymer such as silicone, epoxy resin, urethane, or acrylics, or of a thermoplastic material such as polyethylene, polypropylene, polycarbonate, polyethylene terephthalate, polyacrylate, or acrylonitrile-styrene-butadiene copolymer.

As shown in FIG. 5, the thermally enhanced light emitting device package 50 further comprises a reflector 57 disposed at the peripheries of the encapsulant 54 for reflecting light to increase light intensity and a lens 58 for directing light in the desired direction.

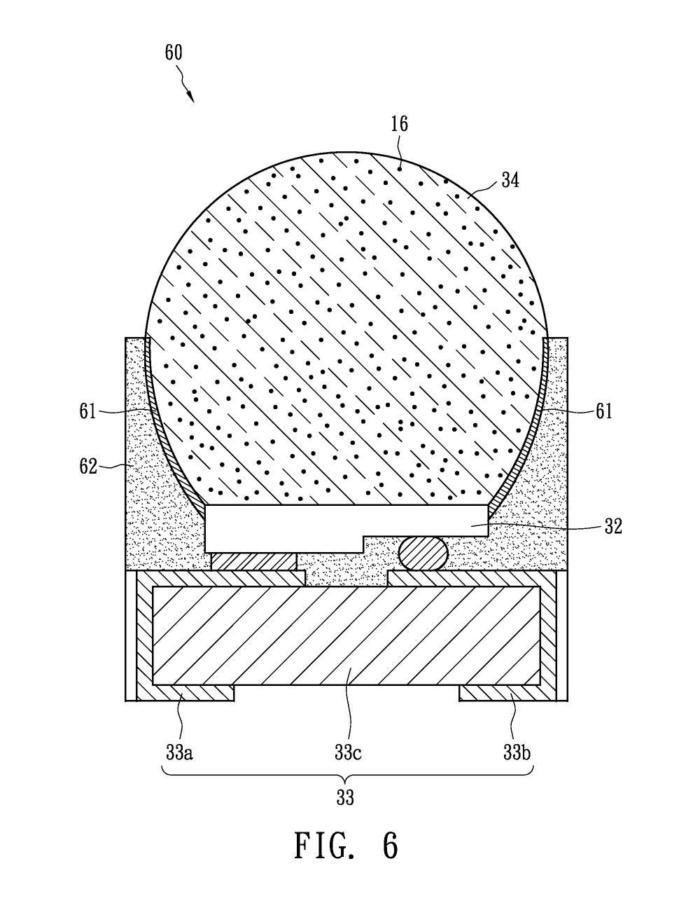

FIG. 6 is a cross-sectional view illustrating a thermally enhanced light emitting device package 60 according to a sixth embodiment of the present invention. Referring to FIG. 6, the thermally enhanced light emitting device package 60 comprises a substrate 33 including a cathode 33a and an is anode 33b, a chip 32 flip-chip bonded to the cathode 33a and the anode 33b, an encapsulant 34 overlaid on the chip 32, and a plurality of non-electrically conductive carbon nanocapsules 16 mixed with the encapsulant 34.

As shown in FIG. 6, the thermally enhanced light emitting device package 60 may further comprise fluorescent powder mixed in the encapsulant 34 to allow the thermally enhanced light emitting device package 60 to simulate white light. The encapsulant 34 is mixed with the plurality of non-electrically conductive carbon nanocapsules 16 so that the heat from the chip 32 can effectively dissipate through the encapsulant 34. The encapsulant 34 can be shaped like a sphere or a partial sphere for directing light in the desired direction.

The thermally enhanced light emitting device package 60 may further comprise an optical element 62 formed at the peripheries of the encapsulant 34 for protection and a reflection layer 61 formed between the optical element 62 and the encapsulant 34 for reflecting the light from the chip 32 to increase light intensity.

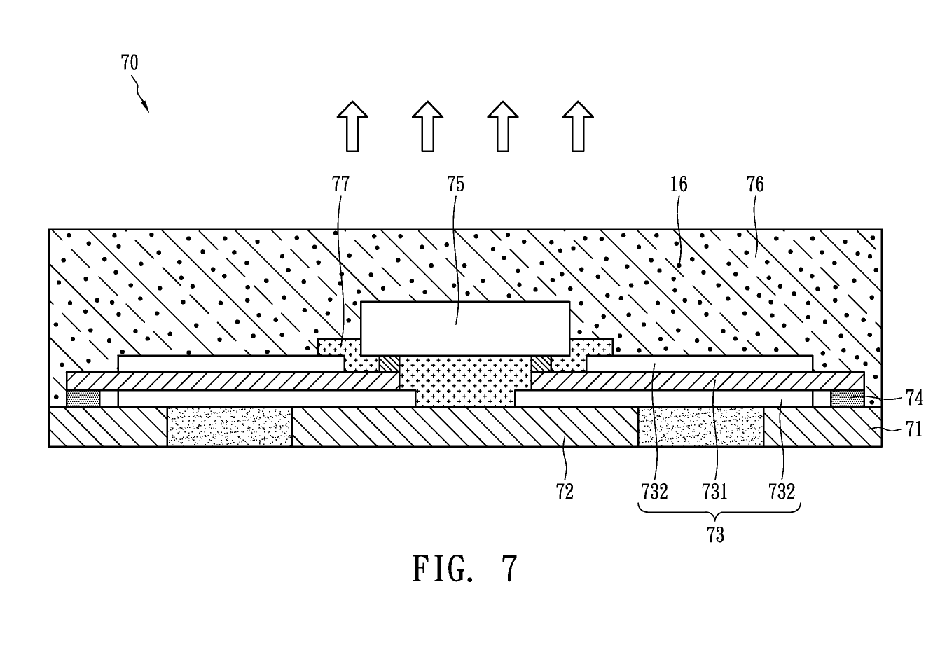

FIG. 7 is a cross-sectional view illustrating a thermally enhanced light emitting device package 70 according to a seventh embodiment of the present invention. Referring to FIG. 7, the thermally enhanced light emitting device package 70 comprises a plurality of contacts 71, a thermal dissipation element 72 disposed between the plurality of contacts 71, a substrate 73 including a patterned metal layer 731, a patterned electrically conductive adhesive layer 74 electrically connecting the plurality of contacts 71 and the metal layer 731, a chip 75 flip-chip bonded to the metal layer 731 and thermally coupled to the thermal dissipation element 72, an encapsulant 76 encapsulating the chip 75, and a plurality of non-electrically conductive carbon nanocapsules 16 dispersed in the encapsulant 76 to allow heat generated by the chip 75 to effectively dissipate through the encapsulant 76.

The thermal dissipation element 72 can be made of thermally is conductive material such as copper, aluminum, or the like.

The electrically conductive adhesive layer 74 can be comprised of solder material, silver paste, anisotropic conductive film, or the like.

The substrate 73 may further comprise two dielectric layers 732, wherein the metal layer 731 is disposed between the two dielectric layers 732.

The thermally enhanced light emitting device package 70 may comprise fluorescent powder mixed in the encapsulant 76 to allow the thermally enhanced light emitting device package 70 to simulate white light.

The thermally enhanced light emitting device package 70 further comprises an adhesive layer 77 formed between the chip 75 and the thermal dissipation element 72. The adhesive layer 77 bonds the chip 75 and the thermal dissipation element 72 together, and electrically insulates the chip 75 from the thermal dissipation element 72. The adhesive layer 77 may contain a plurality of non-electrically conductive carbon nanocapsules 16 so that the heat generated by the chip 75 can effectively dissipate through the adhesive layer 77.

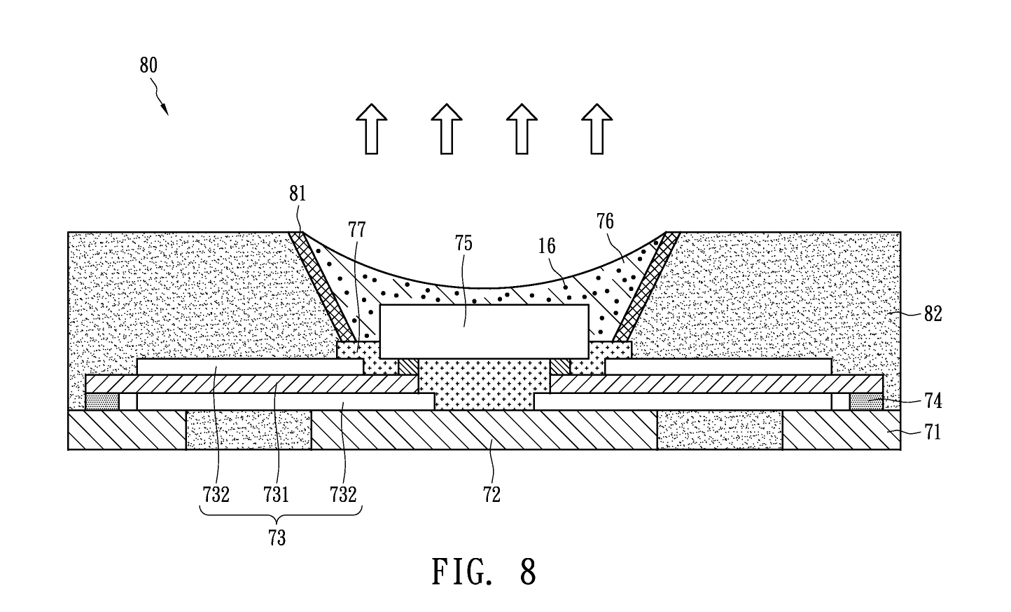

FIG. 8 is a cross-sectional view illustrating a thermally enhanced light emitting device package 80 according to an eighth embodiment of the present invention. Referring to FIG. 8, the thermally enhanced light emitting device package 80 is similar to the thermally enhanced light emitting device package 70 in FIG. 7, while the thermally enhanced light emitting device package 80 further comprises a protection layer 82 having an opening having a shape of a truncated cone, a reflection layer 81 formed on the surface defining the opening, and the encapsulant 76 included in the thermally enhanced light emitting device package 80 contained in the reflection layer 81 and having a curved concave surface. Similarly, a plurality of non-electrically conductive carbon nanocapsules 16 are dispersed in the encapsulant 76 and the adhesive layer 77 to allow heat is generated by the chip 75 to effectively dissipate through the encapsulant 76 and the adhesive layer 77.

The above-described embodiments of the present invention are intended to be illustrative only. Numerous alternative embodiments may be devised by persons skilled in the art without departing from the scope of the following claims.

What is claimed is:

1. A thermally enhanced light emitting device package, comprising:
a leadframe;
a chip attached to the leadframe;
a plurality of metal wires electrically connecting the chip and the leadframe;
a plurality of non-electrically conductive carbon nanocapsules; and
an encapsulant mixed with the non-electrically conductive carbon nanocapsules, encapsulating the leadframe, the chip and the metal wires.

2. The thermally enhanced light emitting device package of claim 1, further comprising a fluorescent adhesive overlaid on the chip.

3. The thermally enhanced light emitting device package of claim 2, wherein the fluorescent adhesive is mixed with the non-electrically is conductive carbon nanocapsules.

4. The thermally enhanced light emitting device package of claim 1, wherein the leadframe includes a downset in which the chip is mounted.

5. The thermally enhanced light emitting device package of claim 1, wherein the encapsulant has a lens part.

6. The thermally enhanced light emitting device package of claim 1, wherein the weight percentage of the non-electrically conductive carbon nanocapsules blended into the encapsulant is less than 10%.

7. A thermally enhanced light emitting device package, comprising:
a substrate;
a chip attached to the substrate;
a plurality of non-electrically conductive carbon nanocapsules; and
an encapsulant mixed with the plurality of non-electrically conductive carbon nanocapsules encapsulating at least part of the substrate and the chip.

8. The thermally enhanced light emitting device package of claim 7, further comprising a plurality of metal wires electrically connecting the chip and the substrate.

9. The thermally enhanced light emitting device package of claim 7, wherein the chip is flip-chip bonded to the substrate.

10. The thermally enhanced light emitting device package of claim 7, further comprising a thermal dissipation element thermally coupled to the chip.

11. The thermally enhanced light emitting device package of claim 10, further comprising an electrically insulating material mixed with non-electrically conductive carbon nanocapsules, covering the thermal dissipation element.

12. The thermally enhanced light emitting device package of claim 11, wherein the weight percentage of the non-electrically conductive carbon nanocapsules blended into the electrical insulating material is less than 10%.

13. The thermally enhanced light emitting device package of claim 10, further comprising an adhesive layer bonding the chip and the thermal dissipation element, and another plurality of non-electrically conductive carbon nanocapsules mixed in the adhesive layer.

14. The thermally enhanced light emitting device package of claim 13, wherein the weight percentage of the another plurality of non-electrically conductive carbon nanocapsules blended into the adhesive layer is less than 10%.

15. The thermally enhanced light emitting device package of claim 7, further comprising a lens disposed on the encapsulant.

16. The thermally enhanced light emitting device package of claim 7, wherein the weight percentage of the non-electrically conductive carbon nanocapsules blended into the encapsulant is less than 10%.

17. The thermally enhanced light emitting device package of claim 7, further comprising a reflector surrounding the encapsulant.

18. The thermally enhanced light emitting device package of claim 7, further comprising an adhesive layer formed around the encapsulant and a reflection layer formed between the adhesive layer and is the encapsulant.

19. A thermally enhanced light emitting device package, comprising:
a substrate;
a chip attached to the substrate;
a plurality of metal wires electrically connecting the chip and the substrate;
an encapsulant mixed with a plurality of non-electrically conductive carbon nanocapsules, encapsulating at least part of the substrate, the wires and the chip;
a lens disposed on the encapsulant; and
another plurality of non-electrically conductive carbon nanocapsules mixed in the lens.

20. The thermally enhanced light emitting device package of claim 19, wherein the weight percentage of the non-electrically conductive carbon nanocapsules blended into the encapsulant is less than 10%.

21. The thermally enhanced light emitting device package of claim 19, further comprising a reflector surrounding the encapsulant.
